(19) United States
(12) Patent Application Publication
(10) Pub. No.: US 2024/0068086 A1
(43) Pub. Date: Feb. 29, 2024

(54) Physical Vapor Deposition (PVD) Chamber Titanium-Tungsten (TiW) Target For Particle Improvement

(71) Applicant: Applied Materials, Inc., Santa Clara, CA (US)

(72) Inventors: Sundarapandian Ramalinga Vijayalakshmi REDDY, Bangalore (IN); Kirankumar Neelasandra SAVANDAIAH, Bangalore (IN); Junqi WEI, Singapore (SG); Bridger Earl HOERNER, Columbia Falls, MT (US); Kelvin Tai Ming BOH, Singapore (SG); Madan Kumar SHIMOGA MYLARAPPA, Bengaluru (IN)

(21) Appl. No.: 18/074,363

(22) Filed: Dec. 2, 2022

Related U.S. Application Data
(60) Provisional application No. 63/401,929, filed on Aug. 29, 2022.

(51) Int. Cl. C23C 14/34

(52) U.S. Cl. CPC C23C 14/3414

(57) ABSTRACT

Target assemblies for PVD chambers are provided herein. In some embodiments, a target assembly for a PVD chamber includes: a backing plate; and a target coupled to the backing plate and having a substrate facing surface opposite the backing plate, wherein a peripheral portion of the target includes an angled surface extending radially outward and toward the backing plate, wherein an annular portion of the angled surface has a surface roughness greater than a surface roughness of a remainder of the substrate facing surface of the target.

### CROSS-REFERENCE TO RELATED APPLICATIONS

This application claims benefit of U.S. provisional patent application Ser. No. 63/401,929, filed Aug. 29, 2022, which is herein incorporated by reference in its entirety.

### FIELD

Embodiments of the present disclosure generally relate to substrate processing equipment.

### BACKGROUND

Tungsten and titanium films are frequently used in the manufacture of semiconductor devices, for example as diffusion barriers between silicon substrates and aluminum alloy metallization. The titanium-tungsten (TiW) films are formed by sputtering titanium-tungsten targets.

During the sputtering process, titanium-tungsten material is sputtered from the surface of the target and deposited onto a substrate disposed opposite the surface of the target. However, the inventors have observed that nodules may form on the sputtering face of the target as material from the central portion of the target is sputtered and redeposited on the outer peripheral edge of the target face rather than on the substrate. Furthermore, the nodules can flake or peel and generate particles that can contaminate and adversely affect the quality of the deposited titanium-tungsten film on the substrate and reduce a lifetime of the target assembly.

Accordingly, the inventors have provided embodiments of improved targets for extending the lifetime of the target assembly.

### SUMMARY

Target assemblies for PVD chambers are provided herein. In some embodiments, a target assembly for a PVD chamber includes: a backing plate; and a target coupled to the backing plate and having a substrate facing surface opposite the backing plate, wherein a peripheral portion of the target includes an angled surface extending radially outward and toward the backing plate, wherein an annular portion of the angled surface has a surface roughness greater than a surface roughness of a remainder of the substrate facing surface of the target.

In some embodiments, a target assembly for a PVD chamber includes: a backing plate; and a target coupled to the backing plate and having a substrate facing surface opposite the backing plate, wherein a peripheral portion of the target includes an angled surface extending radially outward and towards the backing plate, wherein about 45 to about 55 percent of the angled surface has a surface roughness greater than a surface roughness of a remainder of the angled surface.

In some embodiments, a process chamber includes: a chamber body having an interior volume therein; a substrate support disposed in the interior volume for supporting a substrate thereon; and a target assembly a target assembly coupled to the chamber body, the target assembly comprising: a backing plate; and a target coupled to the backing plate and having a substrate facing surface opposite the backing plate, wherein a peripheral portion of the target includes an angled surface extending radially outward and towards the backing plate, wherein a annular portion of the angled surface has a surface roughness greater than a surface roughness of a remainder of the substrate facing surface of the target.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic side view of a PVD chamber in accordance with at least some embodiments of the present disclosure.

FIG. 1B is an enlarged indicated area of detail 1B of FIG. 1A in accordance with at least some embodiments of the present disclosure.

FIG. 2 depicts a bottom view of a target assembly in accordance with at least some embodiments of the present disclosure.

FIG. 3 depicts a cross-sectional side view of a target assembly in accordance with at least some embodiments of the present disclosure.

FIG. 4 depicts an enlarged cross-sectional side view of a portion of a target assembly in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of target assemblies for use in PVD chambers are provided herein. Target assemblies may have a peeling issue, for example, as the target approaches an end of target life, especially at an edge region of the target assembly. Peelings from the target assembly can fall on a substrate being processed in the PVD chamber and contaminate the substrate. However, the inventors have observed that by texturizing certain regions of the target, that the target life, and by extension, the chamber life, can be extended. For example, by texturizing a region proximate the target edge may reduce peeling, prevent peeling, or delay an onset of peeling. The texturizing process may be conducted, for example, via one or more of a twin wire arc spray, an abrasive medium, or the like. In some embodiments, the target assembly may be degreased, cleaned, rinsed, and dried prior to texturizing.

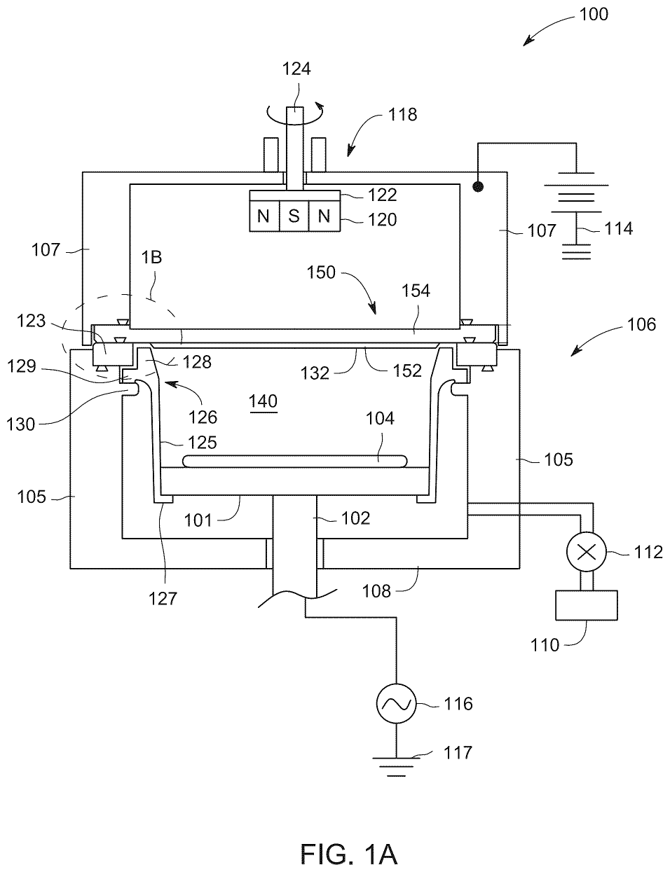

FIG. 1A depicts a schematic side view of a PVD chamber in accordance with at least some embodiments of the present disclosure. FIG. 1B is an enlarged indicated area of detail 1B of FIG. 1A in accordance with at least some embodiments of the present disclosure. Relative terms, such as top, bottom, front, or back are used herein for clarity and consistency with the views shown in the drawings and are not meant to be limiting of the scope of the disclosure, which for example, can be implemented in configurations other than as depicted herein. Generally, the PVD chamber, or process chamber 100, contains a sputtering source, such as target assembly 150 including a target 152 (e.g., source material) and a backing plate 154, which will be described in greater detail below. The process chamber 100 includes a chamber body 106, which together with the target assembly 150, define an interior volume 140 of the process chamber 100. A substrate support 102 for receiving a substrate 104 (e.g., a semiconductor substrate) is disposed in the interior volume 140 opposite the target assembly 150. The chamber body 106 may include sidewalls 105 coupled to a bottom chamber wall 108. The chamber body 106 may be grounded via ground 117. In some embodiments, the chamber body 106 is made of aluminum.

In some embodiments, the target 152 is made of a source material comprising titanium-tungsten (TiW). In some embodiments, the source material consists of essentially of titanium (Ti) and tungsten (W). In some embodiments, the source material of the target 152 comprises about 90 weight percent tungsten (W) and about 10 weight percent titanium (Ti). In some embodiments, the source material of the target 152 has a density (i.e., weight/volume) of at least about 98 percent.

In general, titanium-tungsten targets are fabricated by mixing tungsten raw material powder and titanium raw material powder. The resulting mixture is compacted and heated using a suitable forming method, such as inert gas hot pressing, vacuum hot pressing, hot isostatic pressing, cold pressing/sintering, or the like. The inventors have observed that adjusting the average grain size of the tungsten raw material powders and titanium raw material powders can reduce titanium-rich or tungsten-rich regions and thus advantageously reduce or eliminate nodule formation and peeling. In some embodiments, an average grain size of the titanium powder is less than or equal to an average grain size of the tungsten powder. For example, in some embodiments, the average grain size of the titanium grains is less than about 25 μm, or in some embodiments less than about 20 μm. In some embodiments, the average grain size of the tungsten grains is about 20 μm to about 45 μm.

The substrate support 102 supports the substrate 104 to be sputter coated in planar opposition to a substrate facing surface 132, or sputtering surface, of the target assembly 150. The substrate support 102 has a planar substrate-receiving surface disposed opposite and generally parallel to the sputtering surface of the target assembly 150. The substrate support 102 may be vertically movable through a bellows (not shown) connected to the bottom chamber wall 108 to allow the substrate 104 to be transferred onto the substrate support 102 through a slit valve (not shown) in the lower portion of the chamber body 106 and subsequently raised to a deposition position.

In some embodiments, a grounded conductive cathode assembly 107 is coupled to the sidewalls 105. In some embodiments, a rotatable magnetron 118 is coupled to the grounded conductive cathode assembly 107, positioned in back of the backing plate 154 and the target assembly 150. In some embodiments, the target assembly 150 is coupled to the grounded conductive cathode assembly 107 via fasteners 109 extending through the backing plate 154. The rotatable magnetron 118 can include a plurality of magnets 120 (e.g., magnets shown schematically) supported by a base plate 122 connected to a rotation shaft 124 coincident with a central axis of the chamber body 106 and the substrate 104. The plurality of magnets 120 can be arranged in closed pattern, for example having a kidney shape. The magnets 120 produce a magnetic field within the interior volume 140, generally parallel and close to the substrate facing surface 132 to trap electrons and increase a local plasma density, which in turn can increase a sputtering rate. The magnets 120 produce an electromagnetic field around the top of the process chamber 100, and the magnets 120 can be rotated to rotate the electromagnetic field which influences the plasma density of the process to sputter the target 152 more uniformly.

Processing gas can be supplied from a gas source 110 through a mass flow controller 112 into the interior volume 140, for example, adjacent the substrate support 102. An RF power supply 116 may be connected to the substrate support 102 to induce a negative DC self-bias on the substrate 104—but in other applications the substrate support 102 can be grounded or left electrically floating—and a controllable DC power source 114 coupled to the process chamber 100 may be used to apply a negative voltage or bias to the target assembly 150.

Continuing with reference to FIG. 1A, the process chamber 100 includes a grounded shield 126 having an upper portion 128 including a flange 129 supported on and electrically connected to a ledge 130 of the sidewall 105. The shield 126 also includes an elongated portion 125 that extends downwardly from the upper portion 128 along the sidewalls 105 and a bottom portion 127 that is coupled to a bottom surface 101 of the substrate support 102 via one or more suitable coupling devices (e.g., screws, bolts, clips, etc.). The shield 126 can be formed, for example, from hard, non-magnetic stainless steel.

With reference to FIG. 1B, the upper portion 128 of the shield 126 closely fits in an annular recess formed between a front surface, or substrate facing surface 162 of the backing plate 154 and an outer sidewall 134 of the target 152. An inside corner 136 of the upper portion 128 and the outer sidewall 134 of the target 152 define a gap 138 therebetween. The gap 138 is sufficiently narrow to prevent plasma from penetrating between the inside corner 136 and the outer sidewall 134, hence protecting other components within the process chamber 100 (e.g., a dielectric isolator 123 (FIGS. 1A and 1B) from being sputter coated with a metal layer, which could possibly electrically short the target 152. A top surface 133 of the shield 126 is spaced from the substrate facing surface 162 of the backing plate 154. In some embodiments, the backing plate 154 includes an o-ring groove 172 configured to receive an o-ring 178 that is used to provide a seal between the backing plate 154 and the dielectric isolator 123.

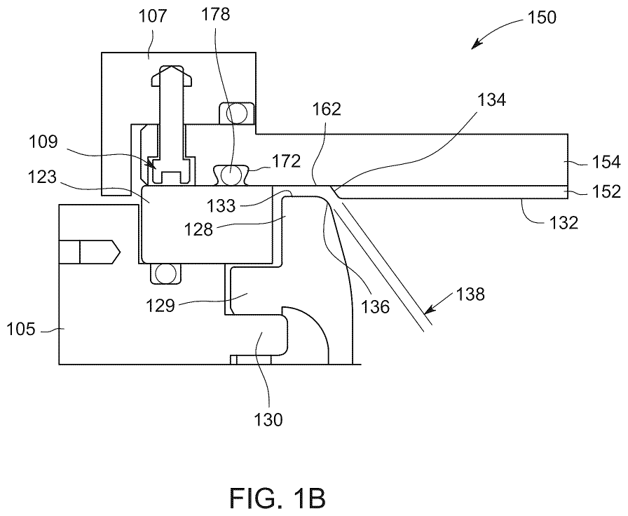

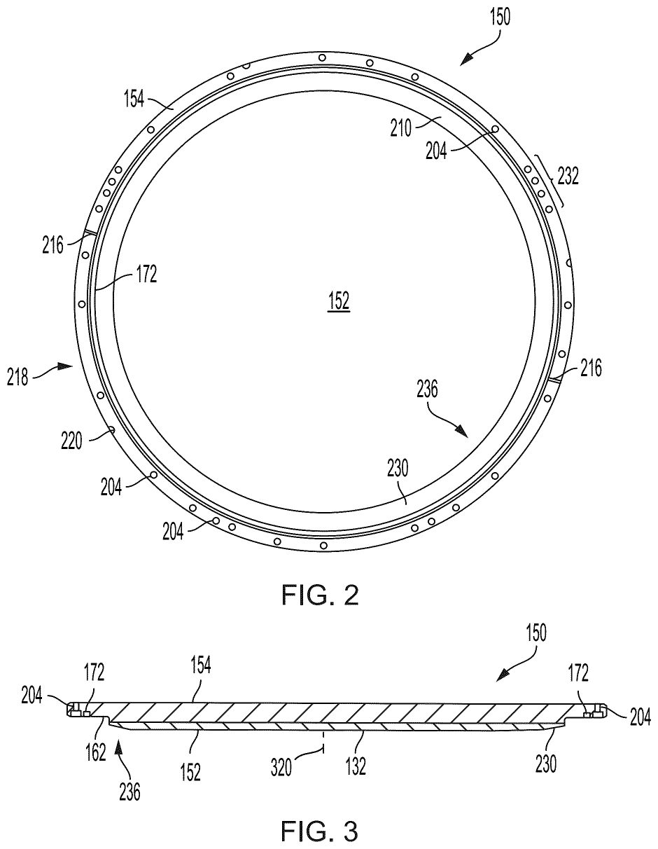

FIG. 2 depicts a bottom view, or substrate facing view, of a target assembly 150 in accordance with at least some embodiments of the present disclosure. FIG. 3 depicts a cross-sectional side view of the target assembly 150 in accordance with at least some embodiments of the present disclosure. The backing plate 154 includes an inner portion 210 for bonding the target 152 to the backing plate 154 and an outer portion 218. The outer portion 218 can include a plurality of features disposed therealong, such as apertures 204, notches 220 (e.g., three), slits 216 (e.g., two), openings 232 for power connection, or the like.

The apertures 204, for example, are configured to receive one or more types of fasteners, e.g., screws, bolts, etc., for mounting the backing plate 154 including the target 152 to the process chamber 100, for example, to the conductive cathode assembly 107. The notches 220 are configured to help align the apertures 204 of the backing plate 154 with corresponding apertures on the conductive cathode assembly 107 when mounting the backing plate 154, for example, to the conductive cathode assembly 107. The backing plate 154 may be mounted via fasteners 109. The slits 216 are configured to provide an exit path for gases from the o-ring groove 172 when the target assembly 200 is installed. The openings 232, for example, may be configured to receive features for coupling the target assembly 150 to a power source (e.g., DC power source 114).

As depicted in FIG. 3, the substrate facing surface 132 of the target 152 includes an angled surface 230 at a peripheral portion 236 of the target 152. The angled surface 230 is disposed radially inward of the outer portion 218 of the backing plate 154. The angled surface 230 is generally annular and extends radially outward and toward the backing plate 154. In some embodiments, the angled surface 230 begins at a distance of about 7.9 to about 8.2 inches from a central axis 320 of the target assembly 150.

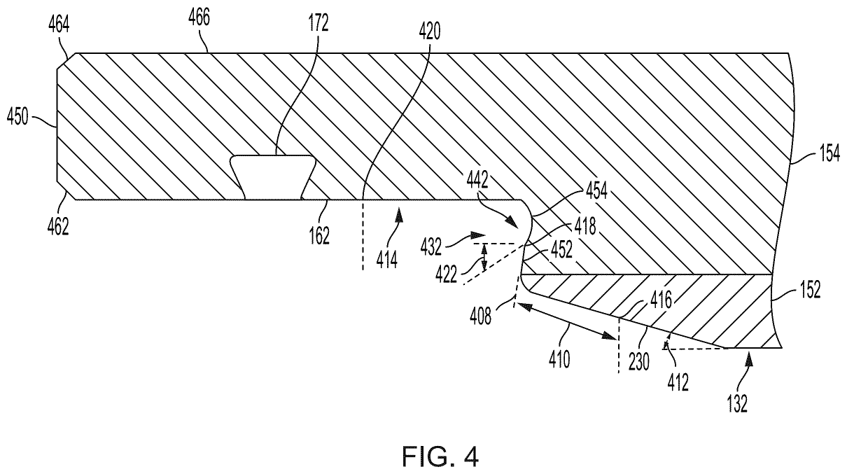

FIG. 4 depicts an enlarged cross-sectional side view of a portion of a target assembly in accordance with at least some embodiments of the present disclosure. An annular portion 410 of the angled surface 230 has a surface roughness greater than a surface roughness of a remainder of the substrate facing surface 132 of the target 152. In some embodiments, the annular portion 410 of the angled surface 230 is about 45 to about 55 percent of a total length of the angled surface 230. In some embodiments, the angled surface 230 extends at an angle 412 of about 12 to about 17 degrees. In some embodiments, the annular portion 410 is a bead blasted surface.

In some embodiments, the surface roughness of the annular portion 410 is greater than about 200 microinches roughness average (RA). For example, in some embodiments, the annular portion 410 has a surface roughness of about 250 to about 300 microinches roughness average (RA). In some embodiments, the annular portion 410 of the angled surface 230 extends from a distance of about 8.1 to about 8.6 inches from the central axis 320 of the target 152 to an outer edge 408 of the target 152, for example, from point 416 to the outer edge 408.

In some embodiments, an inner sidewall 432 of the backing plate 154 adjacent the outer edge 408 of the target 152 has a surface roughness greater than the surface roughness of the remainder of the substrate facing surface 132 of the target 152. In some embodiments, a portion 414 of the substrate facing surface 162 of the backing plate 154 has a surface roughness greater than the remainder of the substrate facing surface 132 of the target 152. In some embodiments, the inner sidewall 432 of the backing plate 154 extends radially inward and away from the target 152.

In some embodiments, the inner sidewall 432 includes a first portion 452 proximate the outer edge 408 and a second portion 454 proximate the substrate facing surface 162. In some embodiments, the inner sidewall 432 includes a step 442 disposed between the first portion 452 and the second portion 454. In some embodiments, the step 442 extends from a point 418 of the inner sidewall 432 to the second portion 454. In some embodiments, the step 442 extends radially inward and upward from the point 418 to the second portion 454. In some embodiments, the step 442 extends at an angle 422 of about 30 to about 40 degrees. In some embodiments, the first portion 452 extends linearly. In some embodiments, the second portion 454 is curved. In some embodiments, the first portion 452 has a surface roughness that is substantially similar to the surface roughness of the annular portion 410. In some embodiments, the first portion 452 is bead blasted. In some embodiments, the first portion 452 has a different surface roughness than the second portion 454.

The backing plate 154 extends radially outward beyond the target 152 and the substrate facing surface 162 of the backing plate 154 extends from the inner sidewall 432 to an outer sidewall 450 of the backing plate 154. In some embodiments, a portion 414 of the substrate facing surface 162 of the backing plate 154 has a surface roughness greater than the remainder of the substrate facing surface 132 of the target 152. In some embodiments, the portion 414 extends from the inner sidewall 432 to a point 420. In some embodiments, the point 420 is disposed about 9 inches to about 9.5 inches from the central axis 320. In some embodiments, the o-ring groove 172 is disposed radially outward of the point 420. In some embodiments, the portion 414 of the backing plate 154 is an arc sprayed surface. In some embodiments, the second portion 454 of the inner sidewall 432 is an arc sprayed surface. In some embodiments, the portion 414 has a surface roughness of about 200 to about 300 microinches roughness average (RA).

In some embodiments, the portion 414 has a surface roughness different than a surface roughness of the first portion 452 and the annular portion 410. In some embodiments, the portion 414 has a same surface roughness as the second portion 454. In some embodiments, the target assembly 150 has a similar surface finish from point 416 to point 418. In some embodiments, the target assembly 150 has a similar surface roughness from point 416 to point 418. In some embodiments, the target assembly 150 has a similar surface finish from point 418 to point 420. In some embodiments, the target assembly 150 has a similar surface roughness from point 418 to point 420. In some embodiments, the outer sidewall 450 includes a first beveled edge 462 adjacent the substrate facing surface 162. In some embodiments, the outer sidewall 450 includes a second beveled edge 464 proximate a back surface 466 of the backing plate 154.

While the foregoing is directed to embodiments of the present disclosure, other and further embodiments of the disclosure may be devised without departing from the basic scope thereof.

1. A target assembly for a PVD chamber, comprising:
a backing plate; and
a target coupled to the backing plate and having a substrate facing surface opposite the backing plate, wherein a peripheral portion of the target includes an angled surface extending radially outward and toward the backing plate, wherein an annular portion of the angled surface has a surface roughness greater than a surface roughness of a remainder of the substrate facing surface of the target.

2. The target assembly of claim 1, wherein an inner sidewall of the backing plate adjacent an outer edge of the target has a surface roughness greater than a surface roughness of the remainder of the substrate facing surface of the target.

3. The target assembly of claim 2, wherein the inner sidewall of the backing plate extends radially inward and away from the target.

4. The target assembly of claim 2, wherein the inner sidewall of the backing plate includes a step.

5. The target assembly of claim 1, wherein the annular portion of the angled surface is about 45 to about 55 percent of a total length of the angled surface.

6. The target assembly of claim 1, wherein the angled surface extends at an angle of about 12 to about 17 degrees.

7. The target assembly of claim 1, wherein the backing plate extends radially outward beyond the target, and wherein the backing plate includes a sidewall extending from an outer edge of the target to a substrate facing surface of the backing plate, and the substrate facing surface of the backing plate extends to an outer sidewall of the backing plate.

8. The target assembly of claim 1, wherein a portion of the substrate facing surface of the backing plate has a surface roughness greater than the remainder of the substrate facing surface of the target.

9. The target assembly of claim 1, wherein the surface roughness of the annular portion of the angled surface is greater than about 200 microinches roughness average (RA).

10. A target assembly for a PVD chamber, comprising:
a backing plate; and
a target coupled to the backing plate and having a substrate facing surface opposite the backing plate, wherein a peripheral portion of the target includes an angled surface extending radially outward and towards the backing plate, wherein about 45 to about 55 percent of the angled surface has a surface roughness greater than a surface roughness of a remainder of the angled surface.

11. The target assembly of claim 10, wherein the target is made of titanium-tungsten (TiW).

12. The target assembly of claim 10, wherein the backing plate includes a substrate facing surface radially outward of the target, and wherein a portion of the substrate facing surface of the backing plate has a surface roughness greater than the remainder of the substrate facing surface of the target.

13. The target assembly of claim 12, wherein the about 45 to about 55 percent of the angled surface is a bead blasted surface, and wherein the portion of the substrate facing surface of the backing plate is an arc sprayed surface.

14. The target assembly of claim 10, wherein the backing plate includes a plurality of apertures for coupling the target assembly to the PVD chamber.

15. The target assembly of claim 10, wherein the backing plate includes an o-ring groove radially outward of the target.

16. A process chamber, comprising:
a chamber body having an interior volume therein;
a substrate support disposed in the interior volume for supporting a substrate thereon; and
a target assembly coupled to the chamber body, the target assembly comprising:
a backing plate; and
a target coupled to the backing plate and having a substrate facing surface opposite the backing plate, wherein a peripheral portion of the target includes an angled surface extending radially outward and towards the backing plate, wherein an annular portion of the angled surface has a surface roughness greater than a surface roughness of a remainder of the substrate facing surface of the target.

17. The process chamber of claim 16, wherein the annular portion of the angled surface is about 45 to about 55 percent of a total length of the angled surface, and wherein the annular portion has a surface roughness of about 200 to about 300 microinches roughness average (RA).

18. The process chamber of claim 16, wherein the target is made of titanium-tungsten (TiW).

19. The process chamber of claim 18, a grain size of tungsten in the target is about 20 to about 45 micrometers and a grain size of titanium in the target is about 20 micrometers or less.

20. The process chamber of claim 16, wherein the annular portion of the angled surface extends at a distance of about 8.1 to about 8.6 inches from a central axis of the target to an outer edge of the target.
